(19) United States
(12) Patent Application Publication
(10) Pub. No.: US 2005/0101116 A1
(43) Pub. Date: May 12, 2005

(54) Integrated circuit device and the manufacturing method thereof

(76) Inventor: Shih-Hsien Tseng, (US)

Correspondence Address: PRO-TECHTOR INTERNATIONAL, 20775 Norada Court, Saratoga, CA, 95070-3018, US

(21) Appl. No.: 10/712,318

(22) Filed: Nov. 12, 2003

(30) Foreign Application Priority Data
Nov. 10, 2003 (TW) 92131370

(51) Int. Cl. H01L 21/4763

(52) U.S. Cl. 438/622

(57) ABSTRACT

An integrated circuit device has a substrate, an interconnection level, a shielding level and a plurality of stitching studs. The substrate has a plurality of active devices, and the stitching studs pass through the substrate. The interconnection level is on the substrate, having a plurality of metal lines to provide interconnections between the active devices with a plurality of plugs. The shielding level is on the interconnection level, having an electromagnetic shielding pattern. The electromagnetic shielding pattern, the plugs, and the stitching studs are connected to form an electromagnetic shielding housing of the integrated circuit device.

### BACKGROUND

1. Field of Invention

This invention relates to an integrated circuit structure and a manufacturing method thereof, and more particularly to the integration of an electromagnetic shielding and interconnect structures of a substrate.

2. Description of Related Art

With the advances of microelectronic manufacturing technology and integrated circuit assembly techniques, a printed circuit board substrate usually comprises a plurality of metal layers, and interconnections therebetween to connect each two or more different metal layers. The multi-layer substrate provides a platform for mounting and interconnecting microelectronics devices and passive electronic devices, such as resistors, capacitors, and inductors. These passive electronic devices perform some pre-designed electronic functions required in electronic systems, such as personal computers, mobile phones, game consoles, personal digital assistants (PDAs), and television sets.

Higher speed and better performance of these electronic systems at smaller, more compact sizes are required to meet the customer's satisfaction. High-speed on-off switching of these electronic systems results in greater electromagnetic radiation or interference. As the operation frequency of the advanced electronic system increases, the amount of pulse steps increases and current thereof also rises, thus generating unwanted voltage drops in the interconnections and causing significant amounts of electromagnetic radiation.

An integrated electronic system formed on a single silicon chip has been developed. However, it is really very difficult to manufacture a complicated and integrated system chip which includes different integrated circuits, such as analog, mixed signal, digital, memory, high speed and low power circuits. Furthermore, when the functions of the system chip and the numbers of interconnection levels increases, power distribution, voltage drops, signal noises and chip I/O pads of the integrated system chip become limiting factors as the chip size thereof is simultaneously decreasing.

An alternative way to achieve this goal is to integrate multi-function chips into a system in a package, which is able to meet the demands of manufacturing small, thin, and light products. A large number of integrated circuit chips therefore need to be mounted or stacked on another lower chip. However, when a plurality of chips is wired and stacked, upper integrated chips contact and press the wirings of the lower integrated chips, and the signal transmission metal lines of the lower integrated chip are easily seriously impacted and thereby damaged.

FIG. 1 is a cross-sectional view of a conventional integrated circuit chip. In FIG. 1, an integrated circuit chip 100 comprises a silicon substrate 101. A device level 102 formed on an upper side of the silicon substrate 101 with a plurality of poly silicon or polycide layers includes a plurality of active devices, such as metal-oxide-silicon (MOS) transistors. A local interconnection level 103 is then formed on the device level 102 for interconnecting the active devices of the device level 102. Moreover, a global interconnection level 104, a metal layer 108 and a passivation level 109 are sequentially formed above the local interconnection level 103.

The global interconnection level 104 includes a plurality of metal layers for connecting global signals and distributing power. A plurality of vias is defined on the passivation level 109 to expose partially the metal layer 108, and electrode pads 106 are formed therein. Furthermore, solder bumps or gold bumps (omitting buried metals) 107 are provided on the electrode pads 106 for external electrical connection.

The silicon substrate 101 generally contains sources, drains, and channels of the active devices of the device level 101. Each layer of the local interconnection level 103 and the global interconnection level 104 may include insulators, conductive plugs, contacts or pre-designed metal or poly patterns. One of the patterns in one layer is electrically connected to another pattern in another layer of the same layer or not by the plugs or contacts.

FIG. 2 illustrates a schematic sectional view of a stacked semiconductor chip. Referring to FIG. 2, a stacked semiconductor chip 200 includes a substrate 202, a lower silicon chip 212, an upper silicon chip 214, a plurality of wirings 216, and adhesive layers 218. The lower silicon chip 212 is attached on the substrate 202 with the adhesive layer 218 and the upper silicon chip 214 is stacked on lower chip 212 by the other adhesive layer 218. According to this structure, the wiring process of the wirings 216 is very complicated and adversely affects the signal transmission or causes a short-circuit between the upper and lower silicon chips 212 and 214.

FIG. 3 is a schematic, cross-sectional view of a BGA-type chip. The BGA-type chip 300 includes a bonding plane 307 and signal leads 303, power leads 304, and ground leads 305 passing through a carrier printed circuit board (PCB) 301 in the vertical direction. The bonding plane 307 covers an upper surface of the carrier PCB 301 except for a protruding end of each electrical connection portion 306. A chip 340 is attached on the bonding plane 307 with an adhesive layer 401. Each bonding wire 402 is connected to each corresponding connecting portion 306 and corresponding bonding pad of the chip 340.

The embedded ground plane 405 is connected to the ground leads 305. The decoupling capacitor 347 is embedded in the carrier PCB 301 and connected between the ground leads 305 and power leads 304. By this configuration, the electromagnetic radiation from the carrier PCB 301 on which these IC devices are mounted can be prevented. However, the crossing electromagnetic radiation between the IC packages still exists and generates noise signals while the chip is in operation.

### SUMMARY

It is therefore an objective of the present invention to provide an integrated circuit device that effectively inhibits electromagnetic interference (EMI) caused by a loop current circuiting between the integrated circuit package and the printed circuit board, and prevents the noise current cause by high-speed switching of the internal power circuit in the silicon integrated circuit device.

It is another an objective of the present invention to provide an integrated circuit device, which is easily assembled and flexibly mass-produced from a whole wafer, and is a miniaturized and highly integrated functional device.

It is still another an objective of the present invention to provide a manufacturing method of an integrated circuit device, which uses stitching studs to replace the conventional wirings and substantially thins the substrate, such that the integrated circuit device is more adaptable to the modern thin, light and small electronic device.

It is further an objective of the present invention to provide a manufacturing method of an integrated circuit device, which connects the electromagnetic shielding pattern, the plugs, and the stitching studs embedded in the substrate to form an electromagnetic shielding housing, for better protecting the integrated circuit device from the electromagnetic interference induced from itself or outer environments.

In accordance with the foregoing and other objectives of the present invention, an integrated circuit device comprises a substrate, an interconnection level, a shielding level and a plurality of stitching studs. The substrate has a plurality of active devices, and the stitching studs pass through the substrate. The interconnection level is on the substrate, having a plurality of metal lines to provide interconnections between the active devices with a plurality of plugs. The shielding level is on the interconnection level, having an electromagnetic shielding pattern. The electromagnetic shielding pattern, the plugs, and the stitching studs are connected to form an electromagnetic shielding housing of the integrated circuit device.

In one preferred embodiment of the invention, a plurality of electrode pads are formed on the shielding level for external electrical connection, and at least one passive element is embedded in the shielding level and electrically connected to the stitching studs and/or to the electrode pads.

Furthermore, in another preferred embodiment, a plurality of integrated circuit devices of the invention, which have different functions, is attached or stacked on each other on the same substrate to obtain a system in package (SIP) module or a compact high-density memory module. The integrated SIP module thus has a good electromagnetic interference shielding which may have passive elements, such as decouple capacitors and inductors for inhibiting the noise signal induced by the highly switching operation of the module.

According to one aspect of the invention, a method is provided to manufacture the integrated circuit device of the invention. A plurality of deep trenches is formed on the upper surface of the substrate. An insulating film is deposited on the deep trenches and then the deep trenches are filled with a conductive material to form stitching plugs which are prepared for forming the stitching studs of the invention.

The stitching plugs are formed from the frontside trenches dug in the upper surface of the substrate by using plasma etching, wet etching, laser drilling or any combination thereof, and then depositing the insulating films, such as silicon dioxide, silicon nitride, other insulating films or any combination thereof, by alternative techniques onto the sidewalls of the embedded trenches. The embedded trenches with insulating films formed thereon are then filled with conductive material such as titanium, titanium nitride, aluminum, copper, mercury, tungsten, amalgam, silver epoxy, solder, conductive polymer, other conductive materials or combinations thereof.

Afterward, the conventional semiconductor process steps for fabricating the active devices on the substrate are implemented, such as forming wirings, electrode pads and passivation layer. An interconnection level is then formed on the active devices, with a plurality of metal lines thereof to provide interconnections between the active devices by a plurality of plugs. Moreover, the shielding level, including a thin dielectric film sandwiched in the electromagnetic shielding pattern, is formed on the interconnection level for manufacturing the passive elements, such as capacitors or inductors. A protective layer is sequentially deposited on the shielding level.

The substrate is thinned directly from a lower surface thereof by using conventional backgrinding and/or subsequent polishing, such as chemical-mechanical polishing, high selective plasma etching, or wet etching steps, to expose the stitching plugs as the stitching studs, which serve as electrode connecting terminals of the integrated circuit device. It is possible to form either the vias with the electrode pads or the protruding stitching studs on one or both surfaces of the integrated circuit device for attaching and/or stacking other integrated circuit devices together, thus obtaining a compact memory module or system in package module.

Several packaging connection techniques and materials, such as an isotropic conductive adhesive layer used in the studs bumping bonding, other conventional surface mounting, under bump metallurgy (UMB), anisotropic connection film (ACF), gold or solder bumping, wiring, ball grid array, flip chip, and/or other metallization can be used in the electrical connection between the stitching studs and/or the electrode pads of the integrated circuits devices, to form a compact memory module or a system in package module.

In other preferred embodiments, the invention provides several different ways for forming the stitching studs. The lower surface of the substrate is etched to form a plurality of backside trenches corresponding to and in contact with the frontside stitching plugs. An insulating film is formed on the sidewalls of the backside trenches and then the backside trenches are filled with a conductive material, thus forming backside stitching plugs. The backside stitching plugs are electrically connected to the frontside plugs, thus forming the stitching studs.

Conversely, it is possible to form the stitching studs directly from the lower backside as external electrode connecting terminals without increasing any weight or bulk of the package thereof. After thinning the substrate or not, the backside stitching stud is formed by a single backside trench which passes thorough the substrate from the lower surface to the upper surface thereof, and is also covered with an insulating film. The stitching stud is connected to an electrical connection layer whose material is a poly layer or polycide, a contact plug, or a metal layer fabricated in the integrated circuit device.

The present invention provides a critical solution for the compact electronic devices which have high-speed operation frequency and highly integrated functional circuit blocks. The compact electronic devices generally are formed on a microelectronic substrate, such as a bulk silicon substrate, a silicon-on-insulator (SOI) substrate or a GaAs substrate. The invention can integrate a variety of different integrated circuit chips in a precise alignment for forming a system-in-package module or a compact memory module.

The alignment, the electromagnetic shielding and the interconnections can be performed with minimal difficulties in the overall processes, and also the passive elements can be integrated in the integrated circuit device. It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a schematic, cross-sectional view of a related art integrated circuit chip;

FIG. 2 is a schematic, cross-sectional view of a stacked semiconductor chip;

FIG. 3 is a schematic, cross-sectional view of a BGA-type chip;

FIG. 4A to FIG. 4D illustrate a manufacturing method of the stitching plugs;

FIG. 5 illustrates a partial schematic view of one embodiment of the invention;

FIG. 6A and FIG. 6B illustrate schematic views of preferred embodiment of the invention;

FIG. 7 illustrates another preferred embodiment of the invention;

FIG. 8 illustrates another preferred embodiment of the invention;

FIG. 9A, FIG. 9B and FIG. 9C particularly illustrate schematic views of three embodiments of the invention depicting how the stitching studs are formed in different ways;

FIG. 10 illustrates one preferred embodiment of the invention;

FIG. 11 illustrates another preferred embodiment of the invention; and

FIG. 12 illustrates another preferred embodiment of the invention.

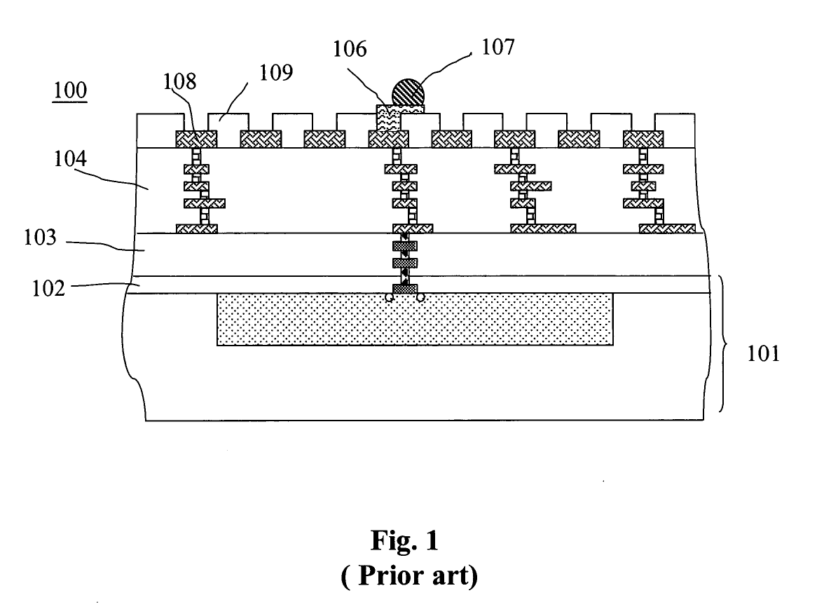

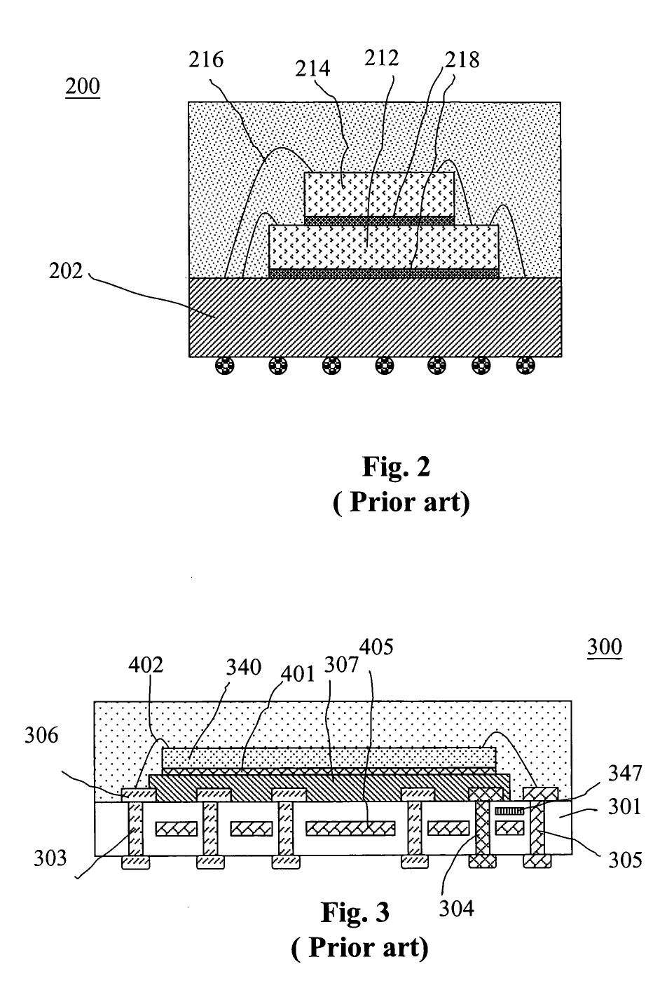

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

According to the present inventions, an integrated circuit device including a substrate, an interconnection level, a shielding level and a plurality of stitching studs is fabricated. The stitching studs pass through the substrate, extending to both surfaces of the substrate. In the invention, these stitching studs are formed by single trenches etched from the frontside surface or the backside surface, or by two mated trenches etched from both surfaces of the substrate. Then an insulating film is deposited in the trenches and the trenches are subsequently filled with a conductive material.

In the embodiments discussed below, two different types of application are present. The first example illustrates a stacked memory module with vertical electrical connections therein that use the anisotropic conductive films (ACF) to connect the stitching studs and electrode pads. Moreover, under-bump metallurgy (UBM), solder bumps and/or other metallizations may be used on the studs or pads of the integrated circuit devices. The second example illustrates a system-in-package module slimier to the first example.

Both configurations of the modules as described above include the embedded electromagnetic shieldings to inhibit the electromagnetic radiation due to the high frequencies switching in the advanced and compact electronic devices.

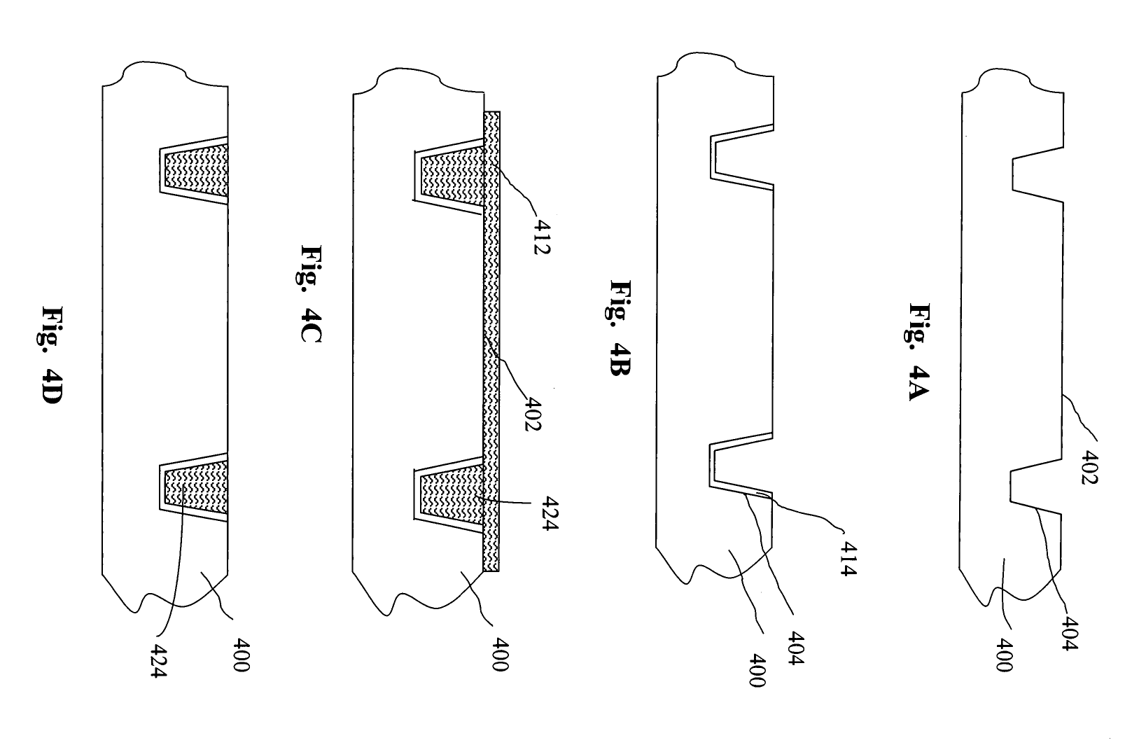

FIG. 4A to FIG. 4D illustrate a manufacturing method of the stitching plugs. Referring to FIG. 4A, a substrate 400 is etched on an upper surface 402 thereof to form a plurality of trenches 404. In one embodiment of this present invention, the trenches 404 can be formed on a silicon semiconductor substrate or other silicon semiconductor substrate with a sapphire layer thereof, for example, those substrates used in a semiconductor over insulator (SOI) technology, or even other plastic or glass substrates.

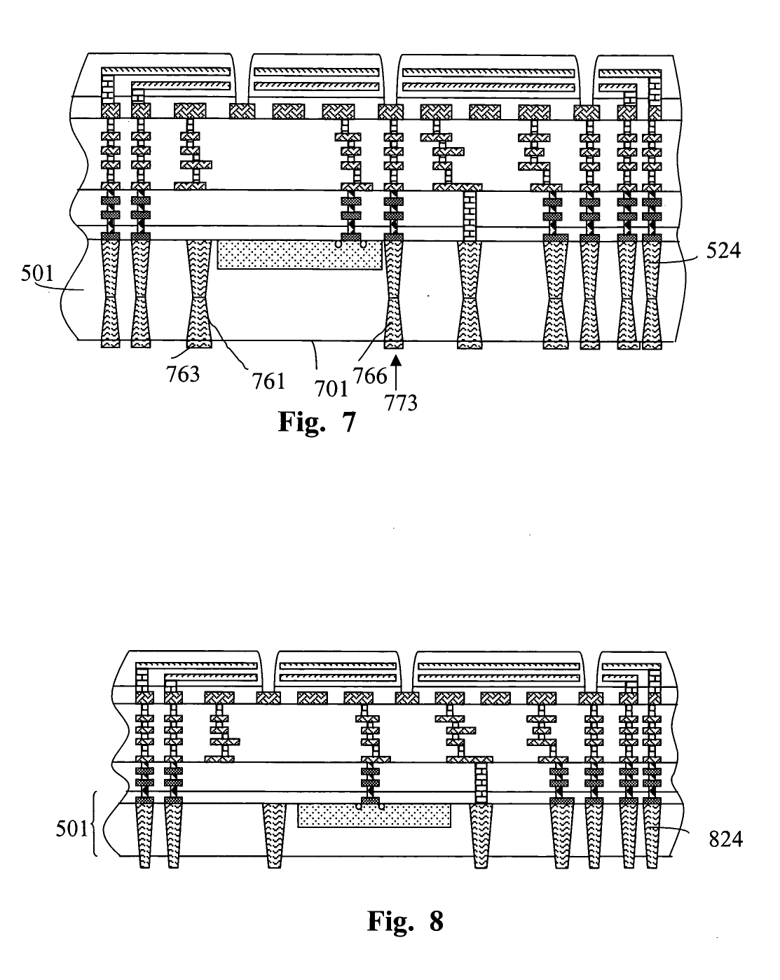

As illustrated in FIG. 4B, for isolating the trenches 404, insulating films 414 are formed inside the trenches 404, including an oxidization film and/or an additional silicon nitride film. After that, the trenches 404 are filled with a conductive material to form the stitching plugs 424, as illustrated in FIG. 7C. In one preferred embodiment of the invention, the conductive material is either titanium or titanium nitride when the buried metals and tungsten serve as the electrical connection plug. In other preferred embodiments, the conductive material is titanium, titanium nitride, aluminum, copper, mercury, tungsten, amalgam, silver epoxy, solder, conductive polymer, other conductive material, or their combinations.

While filling the conductive material into the trenches 404, a redundant metal layer 412 may be formed on the upper surface 402 of the substrate 400. Chemical-mechanical-polishing (CMP), wet etching, plasma etching back process or a combination thereof is therefore applied to remove the redundant metal layer 412 and accomplish the isolated stitching plugs 424, as illustrated in FIG. 4D. These stitching plugs 424 embedded inside the substrate 400 are expected to be outer electrode pads after sequential implementation. Generally, when the stitching plugs 424 are formed in the whole manufacturing process for the integrated circuit device is flexible. For example, the step of forming the stitching plugs 424 can be carried out before or after the step of forming an interlayer dielectric layer (ILD), metals layers, forming contact or plug layers, forming poly layers, or forming the active devices of the integrated circuit device.

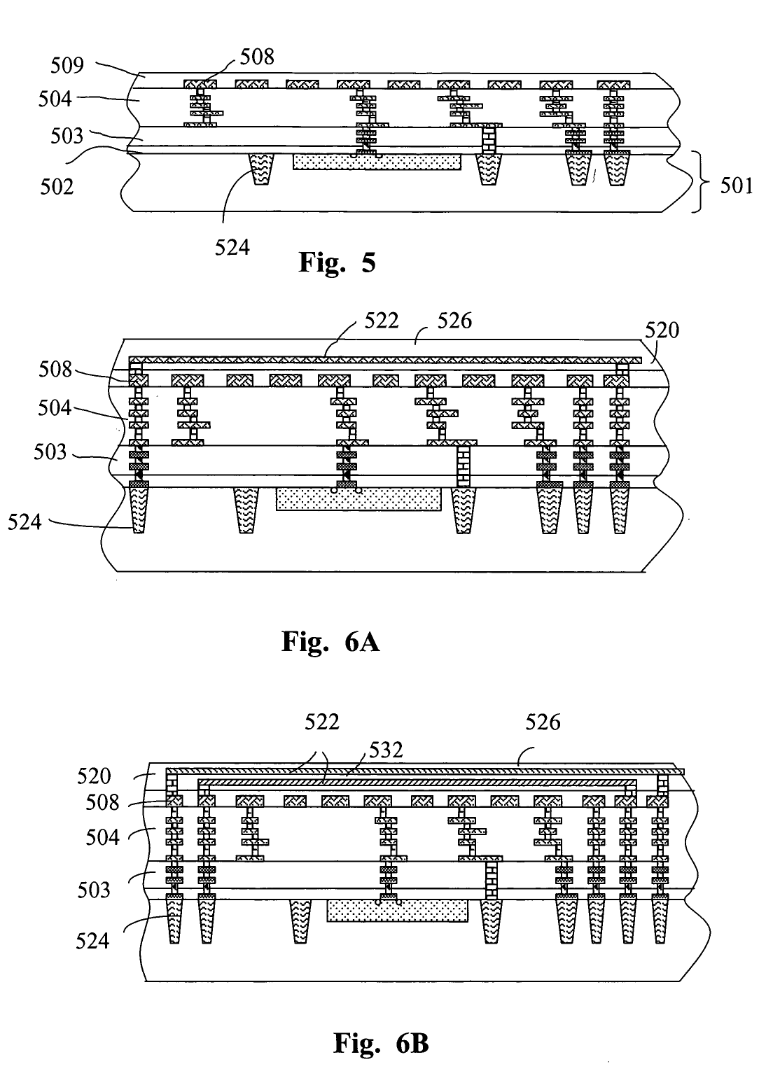

FIG. 5 illustrates a partial schematic view of one embodiment of the invention. An integrated circuit device 500 is fabricated on a silicon substrate 501 with stitching plugs 524 embedded therein. A device level 502 having a plurality of active devices is on an upper side of the substrate 501. Sources, drains, channels of the active devices generally are contained in the substrate 501, and gate oxide and gates of the active devices are then formed thereon. A local interconnection level 503 including polycide and dielectric layers is then formed on the device level 502 for interconnecting the active devices of the device level 502.

Moreover, a global interconnection layers 504, having metals layers, plugs and inter-metal dielectric layers, is above the global interconnection layer. A metal layer is formed on the global interconnection layer 504, and is defined as external electrical electrode pads 508, which are covered by an protective level 509 for protection. The electrode pads 508 are typically formed with multiple layers including a buried metal layer and may be interposed with metallizations, such as Under-bump Metallurgy (UBM), or solder bumps, generally above the electrode pads 508.

FIG. 6A and FIG. 6B illustrate schematic views of a preferred embodiment of the invention. In the embodiments, a shielding level 520 is configured on the integrated circuit device, which has an electromagnetic shielding pattern 522, as illustrated in FIG. 6A and FIG. 6B. In addition, the electromagnetic shielding pattern 522 is electrically connected to the stitching plugs 524 by the plugs in the global and local interconnection layers 504 and 503.

In FIG. 6B, the electromagnetic shielding pattern 522 has more than one conductive layer, and a thin dielectric layer 532 is sandwiched therebetween. In this embodiment of FIG. 6B, the conductive layers are further defined as passive components, such as capacitors and inductors. These passive components are used to inhibit the electromagnetic radiation induced by the high-speed switching operations of the integrated circuit device, for example, the high-speed switching of power signals.

Therefore, the two layers are separately electrically connected to different stitching plugs 524 by different plugs in the global and local interconnection layers 504 and 503, which are electrically coupled to different voltages. The shielding level 520 further comprises a protective material 526, which is deposited on the top of the electromagnetic shielding pattern 522 for protecting the wafer from scratching and external damage.

Thereafter, the substrate 501 is thinned from the lower surface thereof by using conventional backgrinding and/or followed polishing, such as chemical-mechanical polishing, high selective plasma etching, or wet etching steps. In one preferred embodiment interpreted as follows, by thinning the substrate 501, the stitching plugs 524 are further exposed to serve as the stitching studs, which serve in turn as electrode connecting terminals of the integrated circuit device.

FIG. 7 illustrates another preferred embodiment of the invention, for interpreting one way of forming the stitching studs. The embodiment provides another better method to form the stitching studs, in the following description, with regard to the thickness variation of the whole wafer after thinning the substrate 501 when the thickness thereof is less than 150 micrometers by the whole wafer thinning process.

In FIG. 7, backside trenches 761 are formed in the lower surface 701 of the substrate 501, which are expected to match up with the embedded frontside stitching plugs 524 with insulating films previously formed from the upper surface of the substrate 501. As a result, the trenches 761 are completely coupled to the stitching plugs 524 through the substrate 501. It is noted that, in this embodiment, the substrate 501 can be thinned before the backside trenches 761 are formed, or after the stitching plugs 766 are formed.

Similar to the frontside trenches 524 on the upper surface of the substrate 501 for forming the frontside stitching plugs, the backside trenches 761 are formed by chemical etching, plasma etching or laser drilling in the backside surface 701. An insulating film is then formed on the exposed sidewalls of backside trenches 761, from silicon oxidation, silicon nitride or polymer resin. The backside trenches 761 having the insulating film are filled with a conductive material, such as titanium, titanium nitride, solder, copper, mercury, amalgam, aluminum, silver epoxy, conductive polymer, other conductive material or combinations thereof to form the stitching plugs 766.

The lower surface 701 of the substrate 501 is sequentially patterned and etched to form stitching stud pads 763, and thus forming the stitching studs 773. In another embodiment, simple stitching studs are formed merely by the stitching plugs 766 and the insulating film, without the additional stitching stud pads 763.

FIG. 8 illustrates another preferred embodiment of the invention, for interpreting another forming way of the stitching studs. The frontside plugs are exposed to serve as the stitching studs 824, which are formed by thinning the substrate 501 directly and/or performing the high selective etching process on the backside surface of the substrate 501, and further may be in a whole or partial wafer processing. In another embodiment of the invention, the stitching studs also can be formed completely by just the backside plugs, which pass thorough the substrate from the lower surface to the upper surface thereof.

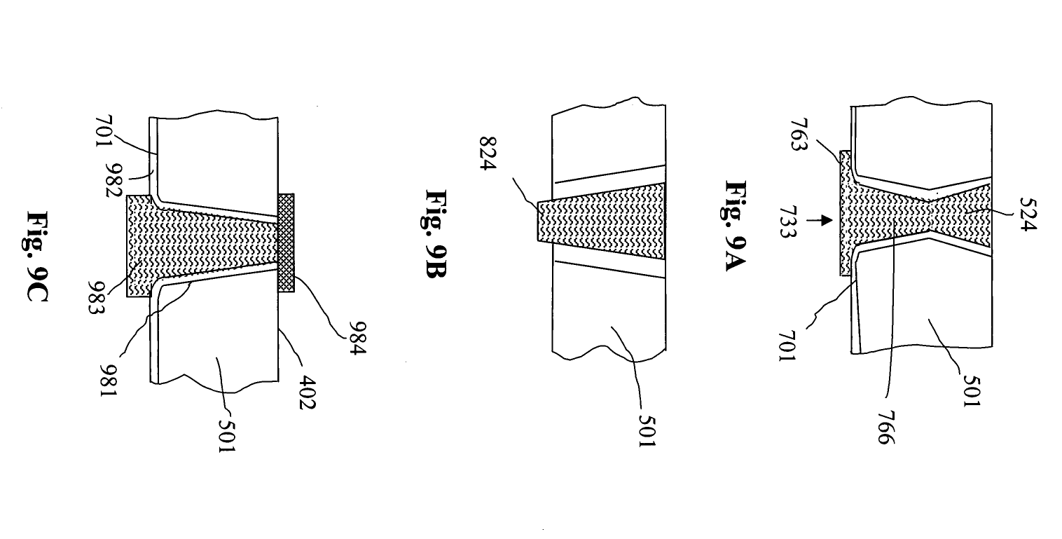

As illustrated above, the stitching studs of the invention can be formed in many alternative ways. FIGS. 9A-9C particularly illustrate schematic views of three embodiments of the invention depicting how the stitching studs may be formed in different ways. The two embodiments in FIG. 9A and FIG. 9B are interpreted according to the foregoing descriptions for FIG. 7 and FIG. 8, respectively.

As illustrated in FIG. 9C, after thinning the substrate 501 or not, a backside stitching stud 983 is formed by a single backside trench 981 which passes thorough the substrate 501 from the lower surface 701 to the upper surface 402 thereof, and also is covered with an insulating film 982. The stitching stud 983 is connected to an electrical connection layer 984 whose material is a poly layer or polycide, a contact plug, or a metal layer fabricated in the integrated circuit device.

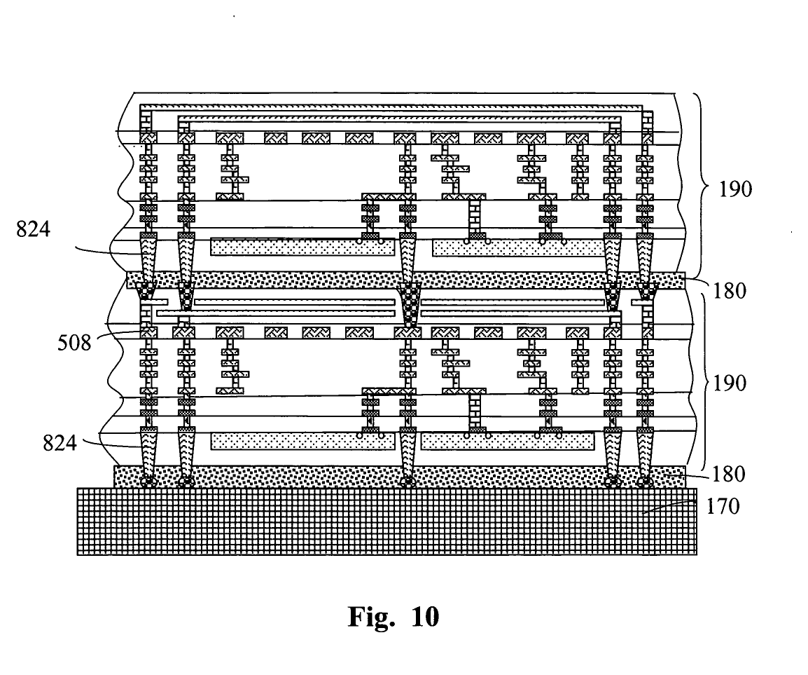

FIG. 10 illustrates one preferred embodiment of the invention. In the preferred embodiment, two wafers having different integrated circuit devices can be stacked together before being diced into individual dices, or, conversely, can be diced first and then stacked. As illustrated in FIG. 10, two memory chips 190 are stacked on a carrier board 170 by using anisotropic conductive films 180, or other adhesive layers or solder bumps. A stacked integrated circuit device is accomplished by bonding the stitching studs 824 and the electrode pads 508 with the offered anisotropic conductive films 180, which can further be inserted with re-distributed wiring layers therein.

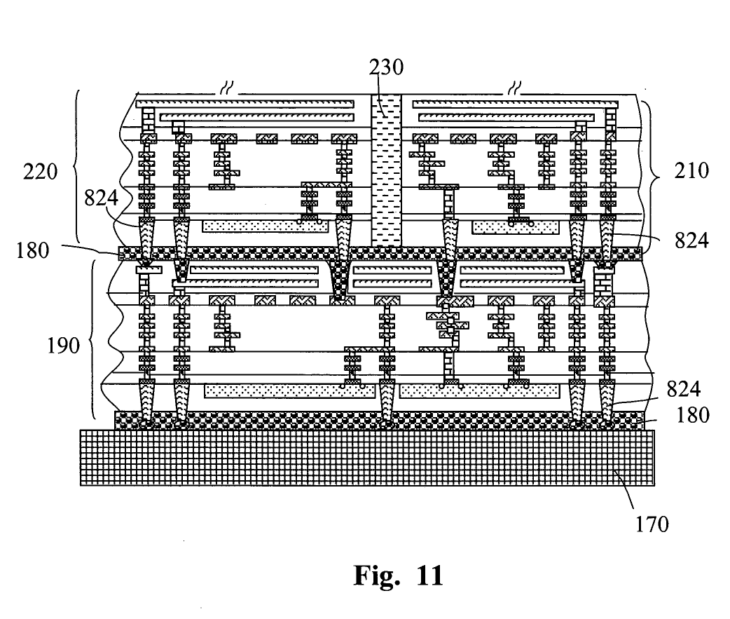

FIG. 11 illustrates another preferred embodiment of the invention. In the embodiment, a stacked integrated circuit device, i.e. a system in package device, includes different functional integrated devices. As illustrated in FIG. 11, a microprocessor chip 210, an analog chip 220, and an memory chip 190 are stacked on the carrier board 170 by using the anisotropic conductive films 180, or other adhesive layers or solder bumps. The system in package device is accomplished by bonding the stitching studs 824 and the electrode pads 508 of the chips with the offered anisotropic conductive films 180, which can further be inserted with re-distributed wiring layers therein. In addition, a protective material 230 fills between the adjacent chips, such as the microprocessor chip 210 and the analog chip 220, to help fix the attached integrated circuit chips on the carrier board 170.

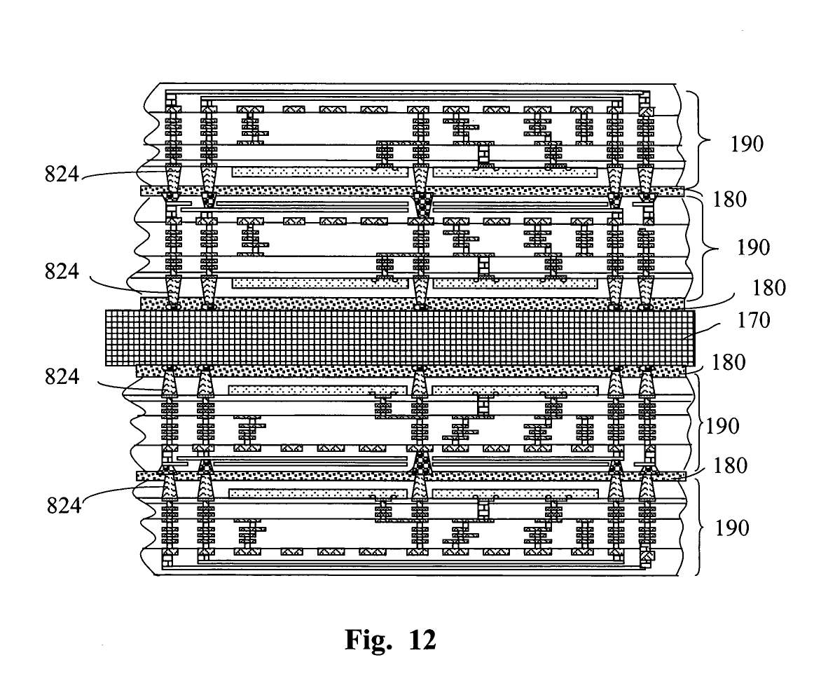

FIG. 12 illustrates another preferred embodiment of the invention. In the preferred embodiment, a plurality of memory chips 190 is integrated and stacked on both sides of the carrier board 170 to form a compact high density memory module. A compact memory module device is accomplished by bonding the stitching studs 824 and the electrode pads 508 of the memory chips 190 with the offered anisotropic conductive films 180, which further can be inserted with re-distributed wiring layers therein.

Moreover, the manufacturing of the embodiment is suitable for a whole wafer processing which can reduce the high labor cost for assembling the memory module. It is noted that in the preferred embodiments as described above, the structures all include the shielding level having an electromagnetic shielding pattern, for inhibiting the induced EMI from the devices or the outer environment.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An integrated circuit device, comprising:
a substrate having a plurality of active devices;
an interconnection level on the active devices, having a plurality of metal lines to provide interconnections between the active devices with a plurality of plugs;
a shielding level on the interconnection level, having an electromagnetic shielding pattern; and
a plurality of stitching studs passing through the substrate;
wherein the electromagnetic shielding pattern, the plugs, and the stitching studs are electrically connected to form an electromagnetic shielding housing of the integrated circuit device.

2. The integrated circuit device of claim 1, wherein the integrated circuit device further comprises:
a plurality of electrode pads formed on the shielding level for external electrical connection.

3. The integrated circuit device of claim 1, wherein the shielding level further comprises at least one passive element embedded in the shielding level.

4. The integrated circuit device of claim 1, wherein the integrated circuit device further comprises a protective level on the shielding level for protecting the integrated circuit device.

5. A manufacturing method of an integrated circuit device, comprising:
providing a substrate;
forming a plurality of active devices on a first surface of the substrate;
forming a plurality of stitching studs passing through the substrate, comprising:
forming a plurality of trenches in a second surface of the substrate;
forming insulating films inside the trenches; and
filling the trenches with a conductive material to form the stitching studs;
thinning the substrate from the second surface;
forming an interconnection level on the active devices, wherein the interconnection level has a plurality of metal lines to provide interconnections between the active devices with a plurality of plugs; and
forming a shielding level on the interconnection level, wherein the shielding level has an electromagnetic shielding pattern;
wherein the electromagnetic shielding pattern, the plugs, and the stitching studs are electrically connected to form an electromagnetic shielding housing of the integrated circuit device.

6. The manufacturing method of claim 5, wherein the manufacturing method further comprises:
forming a plurality of electrode pads on the shielding level for external electrical connection.

7. The manufacturing method of claim 5, wherein the shielding level further comprises at least one passive element embedded in the shielding level.

8. The manufacturing method of claim 5, wherein the manufacturing method further comprises forming a protective level on the shielding level for protecting the integrated circuit device.

9. The manufacturing method of claim 5, wherein the step of thinning the substrate is before the step of forming the stitching studs.

10. The manufacturing method of claim 5, wherein the manufacturing method further comprises:
forming a plurality of stitching stud pads on the second surface with respect to the stitching studs.

11. A manufacturing method of an integrated circuit device, comprising:
providing a substrate;
forming a plurality of active devices on a first surface of the substrate;
forming a plurality of stitching studs passing through the substrate, comprising:
forming a plurality of first trenches in the first surface of the substrate;
forming a plurality of second trenches in a second surface of the substrate, wherein the second trenches match up with the first trenches;
forming insulating films inside the trenches; and
filling the trenches with a conductive material to form the stitching studs;
thinning the substrate from the second surface;
forming an interconnection level on the active devices, wherein the interconnection level has a plurality of metal lines to provide interconnections between the active devices with a plurality of plugs; and
forming a shielding level on the interconnection level, wherein the shielding level has an electromagnetic shielding pattern;
wherein the electromagnetic shielding pattern, the plugs, and the stitching studs are electrically connected to form an electromagnetic shielding housing of the integrated circuit device.

12. The manufacturing method of claim 11, wherein the steps of forming the insulating films inside and filling the first trenches and the second trenches with a conductive material are separate steps.

13. The manufacturing method of claim 11, wherein the manufacturing method further comprises:
forming a plurality of electrode pads on the shielding level for external electrical connection.

14. The manufacturing method of claim 11, wherein the shielding level further comprises at least one passive element embedded in the shielding level.

15. The manufacturing method of claim 11, wherein the manufacturing method further comprises forming a protective level on the shielding level for protecting the integrated circuit device.

16. The manufacturing method of claim 11, wherein the step of thinning the substrate is before the step of forming the second trenches.
